(19) United States
(12) Patent Application Publication
(10) Pub. No.: US 2015/0188052 A1
(43) Pub. Date: Jul. 2, 2015

(54) ORGANIC ELECTRONIC DEVICE MANUFACTURING TECHNIQUES

(71) Applicant: Cambridge Display Technology Limited, Godmanchester (GB)

(72) Inventor: Jeremy Burroughes, Godmanchester (GB)

(21) Appl. No.: 14/410,859

(22) PCT Filed: Jun. 27, 2013
(86) PCT No.: PCT/GB2013/000284

§ 371 Date: Dec. 23, 2014

(30) Foreign Application Priority Data
Jul. 3, 2012 (GB) 1211786.7

(51) Int. Cl. H01L 51/00; H01L 51/56

(52) U.S. Cl. CPC H01L 51/0026; H01L 51/56; H01L 51/0096; H01L 51/0021; H01L 51/0013; H01L 51/0014; H01L 51/5012

(57) ABSTRACT

We describe method of manufacturing an organic electronic device, the method comprising: providing an intermediate stage substrate (200), the substrate bearing a plurality of layers of material of said organic electronic device, the layers including at least one conducting layer in thermal contact with at least one organic layer of said organic electronic device; processing said intermediate stage substrate by inductive heating of said conducting material to heat said at least one organic layer to produce a processed substrate; and using said processed substrate to provide said organic electronic device.

### FIELD OF THE INVENTION

This invention relates to improved techniques for manufacturing organic electronic devices, in particular OLEDs (Organic Light Emitting Diodes), especially polymer OLEDs, and to devices manufactured by these techniques.

### BACKGROUND TO THE INVENTION

Organic electronic devices provide many potential advantages including inexpensive, low temperature, large scale fabrication on a variety of substrates including glass and plastic. Organic light emitting diode displays provide additional advantages as compared with other display technologies—in particular they are bright, colourful, fast-switching and provide a wide viewing angle. OLED devices (which here includes organometallic devices and devices including one or more phosphors) may be fabricated using either polymers or small molecules in a range of colours and in multicoloured displays depending upon the materials used. For general background information reference may be made, for example, to WO90/13148, WO95/06400, WO99/48160 and U.S. Pat. No. 4,539,570, as well as to “Organic Light Emitting Materials and Devices” edited by Zhigang Li and Hong Meng, CRC Press (2007), ISBN 10: 1-57444-574X, which describes a number of materials and devices, both small molecule and polymer.

US2007/0122936 describes a technique for annealing a semiconductor backplane of a flat display panel but does not consider the fabrication of organic electronic devices. To realise some of the fabrication advantages of organic electronics devices improved manufacturing techniques are desirable.

### SUMMARY OF THE INVENTION

According to a first aspect of the invention there is therefore provided a method of manufacturing an organic electronic device, the method comprising: providing an intermediate stage substrate, the substrate bearing a plurality of layers of material of said organic electronic device, the layers including at least one conducting layer in thermal contact with at least one organic layer of said organic electronic device; processing said intermediate stage substrate by inductive heating of said conducting material to heat said at least one organic layer to produce a processed substrate; and using said processed substrate to provide said organic electronic device.

In embodiments employing inductive heating of the organic layer via a nearby, in embodiments adjacent, layer of conducting material provides a number of advantages including in particular localisation of the heating. This in turn provides more accurate control of the manufacturing process, reduces the risk of heating portions of the device which would be better not heated, and can also reduce power consumption for the manufacturing process. Thus, for example, embodiments of the process are particularly useful for plastic substrates where general heating of such substrates is undesirable. A further substantial benefit of embodiments of the method is that they can potentially enable an order of magnitude or more increase in the speed of a polymer cross-linking or annealing process.

Thus in some preferred embodiments the processing by inductive heating is applied to anneal the organic layer and/or to cross-link a polymer layer.

Embodiments of the method can heat the organic layer very rapidly, and this opens up the possibility of heating the organic layer above a temperature which would ordinarily damage the layer, but which is acceptable if the elevated temperature lasts only for a short time. For example an organic material which might only survive 180° C. continuously over a period of, say, an hour, might withstand a temperature close to 300° C. for just a few seconds and remain substantially undamaged. Embodiments of the method deliver relatively small amounts of energy accurately targeted to where the heating is needed, and thus facilitate such rapid heating and cooling. In embodiments of the method this is further facilitated by the layer of conducting material and/or the layer of organic material being of only a very small thickness, for example less than 1000 nm, 500 nm, 200 nm or 100 nm in thickness. Thus, for example, the organic layer may be heated to a temperature of greater than 100° C. or 150° C. in less than 60 seconds and may also cool to less than 100° C. or less than 50° C. in a similar time period.

Such a targeted heating is facilitated by using an RF (radio frequency) transmitting head (coil) which is moved or scanned relative to the substrate just above the substrate, for example less than 5 mm above the substrate. In embodiments use of a high RF frequency, for example greater than 1 GHz, is preferred.

The conducting layer in which eddy currents for the inductive heating are induced may be a metal layer, a transparent conducting oxide layer, or an organic (semi) conductor layer. Although embodiments of the technique are applied to an OLED structure comprising a hole injection layer over an ITO electrode layer, the technique also works with an ITO-free structure in which the (organic) hole injection layer replaces the ITO electrode. In such a case, where a PEDOT hole injection layer is employed optionally this may be used without PSS, for increased conductivity.

Embodiments of the method may also be employed to pattern the organic layer in a pattern corresponding to that of the conducting layer: patterning the conducting layer and then selectively cross-linking an overlying polymer enables the polymer without cross-linking to be washed away by a solvent after the annealing. This technique works best with relatively large areas of underlying electrode but can be useful, for example, to define a region around a perimeter of a device/substrate where there is no electrode, where subsequent deposition can be removed by washing. This facilitates encapsulation of a device or substrate by providing a ‘clean’ region around the perimeter to attach an air/moisture tight cover to the substrate.

As previously mentioned, the substrate may be a plastic or other flexible substrate. Further, embodiments of the technique are suitable for application to a roll-to-roll type manufacturing process. In such an arrangement one or a plurality of RF heads may span a width of the roll-to-roll web or a single head may be scanned back and forth across the web.

In embodiments of the method there is no requirement for the heated organic layer to be adjacent the conducting layer provided there is thermal contact between the conducting layer and the organic layer to be heated. This is particularly the case in fabrication of an organic electronic device such as an OLED where the individual layers may each only be a few 10s of nm in thickness, so that one layer is easily heated through a thickness of one ore more intervening layers. Thus embodiments of the method may additionally include depositing a second organic layer onto the substrate, optionally separated by one or more intermediate layers, and processing this second organic layer, in particular to anneal/cross-link a second polymer layer in a second stage of inductive heating of the conducting material.

In some preferred embodiments the organic electronic device is an OLED device, using either a polymer or small molecule electroluminescent layer. Here what we mean by small molecule is a non-polymeric material such as Alq3, TPO or NBP—for example as described in Chapter 3 of Li and Meng (ibid). In the manufacture of such a device preferably the technique is employed by cross-linking an intermediate layer of polymer organic material over a hole injection layer of the device, using the hole injection layer and/or an underlying ITO electrode layer for the inductive heating. Optionally inductive heating may later be employed in a second stage of the manufacturing process to cross-link one more light emitting layers of the device. This is particularly helpful where the OLED structure includes multiple light emitting layers since in this case it is desirable to cross-link a first-deposited light emitting layer prior to deposition of a subsequent light emitting layer, so that the subsequent layer does not dissolve or attack the underlying light emitting layer. Thus embodiments of the method further comprise cross-linking a first layer of LEP prior to depositing a second LEP layer over this; and optionally cross-linking the second LEP layer prior to depositing a third LEP layer.

The skilled person will appreciate that the techniques we describe are not limited to OLED devices and may also be employed in the fabrication of, for example, an organic photovoltaic (OPV) device and/or an organic thin film transistor, either a top gate device or a bottom gate device.

In a related aspect the invention provides a method of processing an OLED workpiece for manufacturing an OLED, the OLED workpiece comprising a substrate bearing an electrode layer and at least one layer of organic material over said electrode layer, the method comprising heating said electrode layer by inductively coupling an alternating current into said electrode layer.

As previously described, some preferred embodiments of the method scan an RF transmitting head over a surface of the OLED workpiece, a small distance above the surface, to cross-link a layer of polymer organic material.

### BRIEF DESCRIPTION OF THE DRAWINGS

These and other aspects of the invention will now be further described, by way of example only, with reference to the accompanying figures in which:

FIG. 1 shows a first example of a cross section through an OLED structure;

FIG. 2 shows, schematically, an example RF inductive heating and scanning apparatus, and procedure, according to an embodiment of the present invention;

FIG. 3 shows a photograph of an RF head of apparatus for performing a method according to an embodiment of the present invention;

FIG. 4 shows a second example cross section through an OLED structure; and

FIG. 5 shows, schematically, an embodiment of a roll-to-roll manufacturing method according to the invention.

### DETAILED DESCRIPTION OF PREFERRED EMBODIMENTS

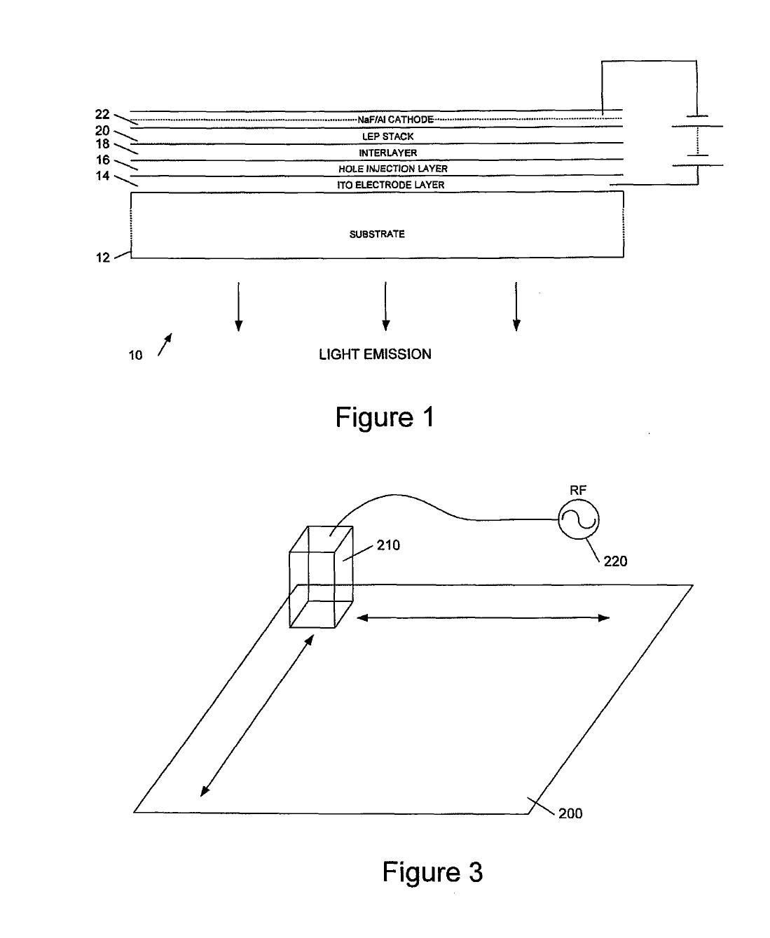

FIG. 1 shows a cross section through a typical OLED device 10. This comprises a substrate 12 bearing a transparent conductive oxide layer 14, typically ITO (Indium Tin Oxide). Over this is deposited a further hole injection layer 16 typically comprising a conducting polymer such as PSS:PEDOT (polystyrene-sulphonate-doped polyethylene-dioxythiophene); this helps match the hole energy levels of the ITO anode and light emitting polymer. The hole injection layer is, in this example, followed by an intermediate polymer layer, interlayer 18. Over this is deposited one or more layers of light emitting polymer (LEP) 20 to form an LEP stack, a typical example of a light emitting polymer is PPV (Poly(p-phenylenevinylene)). A cathode 22 is deposited over the LEP stack, for example comprising a layer of sodium fluoride (NaF) followed by a layer of aluminium. Optionally an additional electron transport layer may be deposited between the LEP stack 20 and cathode 22.

The device illustrated in FIG. 1 is a bottom-emitting device, that is light generated in the LEP stack is coupled out of the device through the substrate, via the transparent ITO anode layer. It is also possible to fabricate top-emitting devices using a thin cathode layer, for example less than around 100 nm in thickness. Although the structure of FIG. 1 shows an LEP stack the same basic structure may also be employed for small molecule (and dendrimer) devices.

Broadly speaking we will describe techniques for annealing, more particularly, cross-linking, organic layers of a device structure such as the above described OLED. In these techniques energy is transferred through inductive coupling of electrical power to one or more conducting layers in the structure, to generate local heating. In a structure such as that shown above the ITO layer is used as the conducting layer to collect the electrical energy. Furthermore, broadly speaking only areas above the ITO are cross-linked, and thus embodiments of the technique may also be employed to pattern the relevant organic layer—in the structure of FIG. 1 for example, interlayer 18. In addition to this the procedure is compatible with roll-to-roll processing and flexible substrates. More particularly to cross-link, for example, interlayer 18 of the structure of FIG. 1 might conventionally require the structure to be baked for a time period of order 1 hour in an oven, whereas various embodiments of the technique we describe can achieve cross-linking in just a few seconds. This offers a substantial reduction in costs through, among other things, a shorter TAC time.

Referring now to FIG. 2, this illustrates, schematically, apparatus and a process for manufacturing an organic electronic device according to an embodiment of the invention. Thus a substrate 200 is mounted on a non-conducting support (not shown in FIG. 2) and a gantry (also not shown) mounts an RF transmitter head 210 in such a manner that the head can be scanned in X- and Y-directions over a surface of substrate 200. The head maintains a distance from the substrate of less than 5 mm, for example around 1 mm (thus embodiments of the technique may couple the near-field electric field of the RF head to the conducting layer). RF head 210 is connected to a source of RF power 220 which drives the head. In one embodiment the RF source 220 is able to provide an RF power up to 100 watts at approximately 2.1 GHz, with a frequency span of approximately 20 MHz. In embodiments the equipment is similar to that employed for rapid electrical sintering (RES); suitable equipment may be obtained from, for example, the VTT Technical Research Centre of Finland, Espoo Finland. In operation the gantry may be configured to sweep the head over substrate 200 at a speed of between 1 mm/s and 25 mm/s.

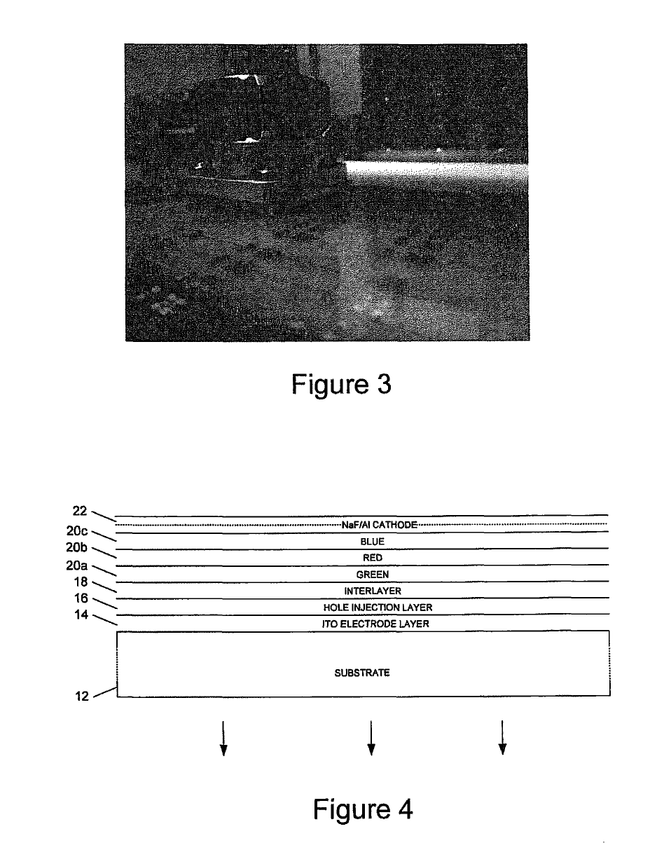

FIG. 3 shows a photograph of the apparatus and method illustrated schematically in FIG. 2, in operation.

Initially, to investigate the technique, interlayer was spun onto glass substrates using spin coating, and the electrical annealing process was employed to cross-link the interlayer. In some example tests of cross-linking of an interlayer, for a power of 100 watts no cross-linking was obtained when the sweep speed was greater than 5 mm/s but successful cross-linking was achieved in a layer of 40 nm thickness when scanning at 1 mm/s. Annealing in layers of thickness 20 nm and 100 nm was achieved at a speed of 2 mm/s; at this speed the overall time of the sample below the head was less than 30 seconds. By contrast 60 minutes at 200° C. was required on a hotplate. If desired the processing speed can be further increased by increasing the RF power.

The skilled person will appreciate that determining the optimum conditions is a matter of routine experiment, given the OLED structure, RF power and head scan speed/distance.

Selective cross-linking only above ITO was also demonstrated. In one example embodiment of the head, inductive coupling of the RF to the ITO was achieved via head coupling electrodes (which may be fabricated on a printed circuit board). With such an arrangement potentially high resolution cross-linking patterning may be achieved by using small sintering head coupling electrodes and, optionally, a reduced working distance.

As previously mentioned, potentially embodiments of the technique facilitate very rapid rise and fall of the temperature of the locally heated region, and thus the annealing may be potentially performed much faster than would normally be expected by exceeding what would generally be a damage threshold for the material were the high temperature to be applied substantially continuously.

Turning next to FIG. 4, this shows a further example of an OLED structure to which embodiments of the method may be applied. The structure of FIG. 4 is for a white OLED and comprises green 20a, red 20b and blue 20c light emitting polymer layers (the red layer also functioning as a triplet diffusion prevention layer). A variant white OLED structure has only two light emitting layers and includes one or more phosphors. In either case, it is desirable to cross-link a lower light emitting layer, for example green layer 20a, prior to spin coating the next light emitting layer so that this subsequent layer does not dissolve the preceding layer.

In one example method of manufacturing a white OLED device of the type illustrated in FIG. 4, initially there is provided a substrate 12 bearing the (optionally patterned) ITO electrode layer 14, typically around 40 nm in thickness. Over this is deposited a hole injection layer 16 of PEDOT, for example around 30 nm in thickness though potentially up to around 150 nm. This layer is then dried. The PEDOT has a work function which hinders the formation of an energy barrier to the injection of holes, and can also assist in planarising the ITO, which is crystalline and may be rough. A similar layer is generally present in an organic photovoltaic device to facilitate the extraction of holes. Commercial hole injection materials are available, inter alia, from Plextronics Inc.

Next, an interlayer 18 typically having a thickness in the range 20 nm to 60 nm is deposited over the hole injection layer and is rapidly cross-linked by a procedure as described above. One example material from which the interlayer may be fabricated is a co-polymer of polyfluorene-triarylamine (or similar). Preferred interlayers comprise one or more fluorene repeat units in combination with one or more amine repeat units, for example as a random co-polymer or as an AB co-polymer. Co-polymers with 30%-60%:70%-40% fluorene:amine units are preferable, for example 30-60% dioctylfluorene and 70-40% amine. In general the co-polymers also have other repeat units, in particular cross-linking units Examples of amine repeat units include TFB and PFB; an example of a cross-linking unit is Benzocyclobutene (BCB) (though the skilled person will appreciate that many other types of cross-linking unit may also be employed). Thus embodiments of the interlayer comprise random or AB copolymers of F8 polyfluorene (ie the 9,9 dioctylfluorene repeat unit) and either TFB or PFB, for example as below (which shows F8, PFB, and TFB respectively):

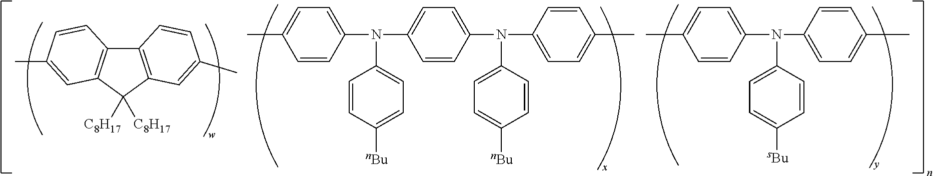

Thus, for example, the interlayer may comprise (without limitation) poly(9,9-dioctylfluorene-co-N-(4-butylphenyl)diphenylamine) and/or poly(9,9′-dioctylfluorene-co-bis-N,N′-(4,butylphenyl)-bis-N,N′-phenyl-1,4-phenylenediamine). Further examples of these and other suitable materials are described by Bradley et al. in Adv. Mater. vol 11, p 241-246 (1999) and in Chapter 2 of Li and Meng (ibid).

Following this step, a first layer 20a of light emitting polymer is deposited and, in an example such as that of FIG. 4 where there are multiple LEP layers, this initial layer is cross-linked, again by the previously described process. Each successive LEP layer 20b, c is also cross-linked if there is an additional LEP layer to be deposited on top. After fabrication of the desired number of LEP layers, the cathode layer 22 is deposited, in embodiments comprising a first layer of sodium fluoride followed by a subsequent layer of aluminium. Although not shown in FIG. 4, optionally the structure may also include an electron transfer layer prior to the cathode layer deposition.

The skilled person will appreciate that there are many variants of an organic electronic device fabrication process in the context of which the techniques we have described may be employed. For example, the ITO layer may be omitted and instead the hole injection layer 16 used as the anode layer. This is potentially advantageous on flexible substrates such as PET (polyethylene terephthalate) or polycarbonate; in this case it may be beneficial to employ PEDOT including a conductivity enhancement agent such as dimethylsulfoxide or ethylene glycol (with or without PSS)—suitable materials are commercially available from Heraeus GmbH, Germany under the name Clevios™. Additionally or alternatively the electrical conductivity of the hole injection layer 16 may be supported by an underlying metallic grid (which may optionally be transparent by using fine grid lines and/or thin metal). Such an approach may be employed, for example, in an OLED lighting tile with a large area of coverage and connections at the edge.

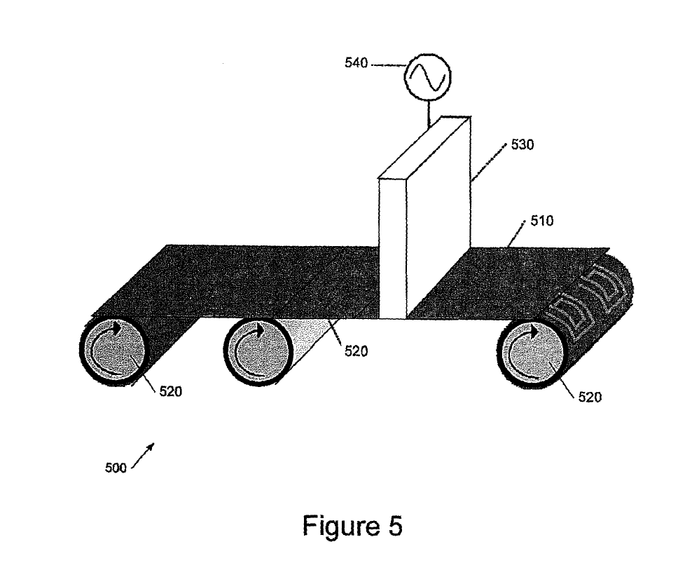

Referring next to FIG. 5, this shows an example method and apparatus 500 for manufacturing an organic electronic device using a roll-to-roll process. In this example a flexible substrate or web 510 for example of PET film, is transported by rollers 520 under an RF head 530 which extends across a width of the web. The RF head is driven by an RF power source 540, as before. As well as various metal oxides and/or PEDOT, a conducting layer may (as in the previous example) also be fabricated from a thin layer of a noble metal such as gold, silver or copper. The organic layer or layers may be deposited using a range of techniques, including, but not limited to, spin coating, inkjet printing, silk screen printing, slot-die coating, gravure printing and flexographic printing. The head 530 may comprise a single, large head or multiple smaller heads or one or more heads scanning back and forth across the web. The RF power may be adjusted dependent upon the manufacturing conditions, distance of the head from web, conducting layer conductivity, cross-linking temperature and the like, by routine experiment.

One of the advantages of the roll-to-roll process of FIG. 5 is the relatively large area, high production speed that such a technique can achieve, and thus embodiments of the techniques are potentially especially beneficial for such a process.

The techniques we have described have many advantages including, but not limited to: low cost (high throughput, low capital cost and low energy usage); compatibility with roll-to-roll processing; the ability to pattern organic layers (as, in embodiments, only the region above the conducting layer is annealed); and compatibility with plastic substrates with lower processing temperatures, (because heat is only locally supplied).

The skilled person will appreciate that many variations of the above described techniques are possible. For example, a lower frequency and/or different configuration of RF (radio Frequency) head may be employed, for example to operate at a frequency of less than 200 MHz or less than 20 MHz. Likewise although we have described annealing interlayer and LEP layers, it will be appreciated that a similar procedure may be employed to anneal, for example, the hole injection layer or other organic layers in an OLED or any other plastic electronic device: the skilled person will recognise that the techniques we have described may be employed in the manufacture of virtually any type of organic electronic device incorporating at least one electrically conducting layer.

As previously described, embodiments of the technique may also be employed to pattern one or more organic layers by using one or more electrically conducting layers to selectively heat and cross-link the organic layers.

No doubt many other effective alternatives will occur to the skilled person. It will be understood that the invention is not limited to the described embodiments and encompasses modifications apparent to those skilled in the art lying within the spirit and scope of the claims appended hereto.

1. A method of manufacturing an organic electronic device, the method comprising:
providing an intermediate stage substrate, the substrate bearing a plurality of layers of material of said organic electronic device, the layers including at least one conducting layer in thermal contact with at least one organic layer of said organic electronic device;
processing said intermediate stage substrate by inductive heating of said conducting layer to heat said at least one organic layer to produce a processed substrate; and
using said processed substrate to provide said organic electronic device.

2. The method as claimed in claim 1 wherein said processing comprises annealing said organic layer.

3. The method as claimed in claim 1, wherein said organic layer comprises a polymer layer and wherein said processing comprises cross-linking said polymer layer.

4. The method as claimed in claim 1, wherein said inductive heating of said organic layer comprises heating to a temperature greater than that which, if applied continuously, would damage the organic layer, the method further comprising controlling a heating/cooling of said organic layer to be sufficiently rapid for said organic layer to be substantially undamaged.

5. The method as claimed in claim 1, comprising, in less than 60 seconds, inductively heating a region of said organic layer to a temperature of greater than 100° C. and then allowing said region of said organic layer to cool to less than 50° C.

6. The method as claimed in claim 1, wherein said induction heating comprises heating with an RF head and moving or scanning one of said substrate and said RF head relative to the other.

7. The method as claimed in claim 6 comprising operating said RF head at a frequency of greater than 1 GHz.

8. The method as claimed in claim 1, wherein said conducting layer comprises a transparent conducting oxide layer.

9. The method as claimed in claim 1, wherein said conducting layer consists of an organic semiconductor layer.

10. The method as claimed in claim 1, further comprising patterning said conducting layer, and wherein said processing comprises correspondingly patterning said organic layer by said inductive heating.

11. The method as claimed in claim 1, wherein said substrate is a plastic substrate.

12. The method as claimed in claim 11, wherein said method of manufacturing comprises a roll-to-roll method of processing said intermediate stage substrate.

13. The method as claimed in claim 1, further comprising depositing a second said organic layer onto said substrate after said inductive heating of said at least one organic layer, and processing said second organic layer in a second stage of inductive heating of said conducting layer.

14. The method as claimed in claim 1, wherein said organic electronic device is an OLED.

15. The method as claimed in claim 14, wherein said providing of said intermediate stage substrate includes depositing a hole injection layer over said substrate, and depositing an intermediate layer of polymer organic material over said hole injection layer, and wherein said inductive heating is used to crosslink said intermediate layer of polymer organic material.

16. The method as claimed in claim 15, further comprising:
depositing a first layer of light emitting polymer LED over said processed substrate;
inductively heating said conducting layer to cross link said first layer of LEP;
depositing at least one further layer of LEP over said cross-linked first layer of LEP, and
depositing a further conducting layer over said at least one further layer of LEP.

17. The method as claimed in claim 1, wherein said organic electronic device is an organic photovoltaic device.

18. The method as claimed in claim 1, wherein said organic electronic device is an organic thin film transistor.

19. A method of processing an OLED workpiece for manufacturing an OLED, the OLED workpiece comprising a substrate bearing an electrode layer and at least one layer of organic material over said electrode layer, the method comprising heating said electrode layer by inductively coupling an alternating current into said electrode layer.

20. The method as claimed in claim 19, wherein said layer of organic material comprises a layer of polymer organic material, the method further comprising scanning an RF transmitting head over a surface of said OLED workpiece to cross-link said layer of polymer organic material.
